(19) United States
(12) Patent Application Publication
(10) Pub. No.: US 2010/0136489 A1
(43) Pub. Date: Jun. 3, 2010

(54) MANUFACTURING DEVICE AND MANUFACTURING METHOD FOR POLYMER WAVEGUIDE DEVICE

(76) Inventors: Chao-Yi TAI, Longtan Shiang (TW); Jia-Wei Tzeng, Yonghe City (TW)

Correspondence Address: SINORICA, LLC, 2275 Research Blvd., Suite 500, ROCKVILLE, MD, 20850, US

(21) Appl. No.: 12/404,465

(22) Filed: Mar. 16, 2009

(30) Foreign Application Priority Data
Dec. 2, 2008 (TW) 097146805

(51) Int. Cl. G03F 7/20; B29C 35/08

(52) U.S. Cl. 430/321; 425/174.4

(57) ABSTRACT

A manufacturing device and a manufacturing method for polymer waveguide devices are revealed. The manufacturing device includes a substrate coated with a photoresist polymer membrane and set on a work platform, a femtosecond laser emitting onto the photoresist polymer membrane, and a lens arranged between the femtosecond laser and the substrate. The polymer waveguide devices are obtained by the femtosecond laser emitting onto the photoresist polymer membrane. Without complicated manufacturing processes, the production efficiency of the polymer waveguide devices is increased.

### FIELD OF INVENTION

The present invention relates to a manufacturing device and a manufacturing method for optical waveguide elements, especially to a manufacturing device and a manufacturing method for polymer waveguide elements.

### DESCRIPTION OF RELATED ART

During the process of exploring light, each step moves quite slow. From totally ignorant of light, knowing more about natures of light, directions and behaviors of light can finally be controlled. Even now, the age of peak scientific achievement, how to control such thing that moves in straight lines and runs the most fast available in the universe is still a challenge for scientists. The development of elements related to optics seems quite slow. Due to broadband characteristics of light, people are urgent to manipulate the lights in the age of information overload.

The velocity of light is the most fast—about three hundred thousand kilometers per second. The coherence of light is maintained and there is no interference between the transmission lines during light transmission. Moreover, the light travels in straight lines so that it changes direction in the form of reflection. Once light transmission and scattering during light transmission processes have been prevented, light transmission controlled artificially is feasible.

Now one of the most hot research topics is integrated optics. The integrated optics is to develop miniaturized optical devices of high functionality on a small piece of film to form an integrated optical circuit applied to various devices. It hopes to put wave guides, modulators, switches, detection and other active optical functions onto one substrate. The integrated optical elements not only have advantages in optics such as increased information capacity, no electromagnetic interference, and parallel processing but also have benefits similar to integrated circuit such as economic effects as well as reliability of all elements in one optical board. Furthermore, the vibration that troubles conventional optical tests disappears after integration of elements. The compact size of the integrated optics (IO) devices makes them attain effective interactions, compared with conventional optical devices. For example, the same electro-optical effect is achieved with smaller voltage and the Electro-optical Effect is used more efficiently to deal with optical signals. After years of development and progress, the manufacturing technique as well as transmission of circuit boards seems to run up against bottlenecks and dead ends under requirements of high intensity, high frequency signal transmission and refinement of wires. Thus the integrated optical circuit will bring their advantages into full play in various applications.

Among integrated optics devices, the waveguide device is one of the most important devices. The waveguide device is applied to transmit optical signals. Conventional way to produce waveguide devices is by optical lithography. The designed figure is made into an optical mask and the waveguide material is coated with photoresists reagents. Based on optical imaging, the figure is projected into the waveguide material. The light passing the optical mask and the lens reacts with photoresist so that portion of the photoresist is exposed. Then the exposed and unexposed photoresists are treated with chemicals and the figure on the optical mask is transferred to the waveguide material completely. However, the optical Lithography includes a plurality of complicated steps and the manufacturing of masks of small-size waveguide devices is more difficult in consideration of cost and size. Moreover, waveguide devices with 45-degree inclined planes are unable to be produced by optical lithography. Thus additional processing is required to produce the inclined planes with an angle of 45 degrees and the cost is increased.

Furthermore, the waveguide devices can also be produced by hot-embossing. In the beginning, a mold is shaped like the waveguide devices by optical lithography or electron beam technology. Then the mold is coated with polymer. After the polymer being molded into waveguide devices, the product is applied with laser precision machining so as to process the waveguide devices with 45 degree inclined planes. However, the laser precision machining requires precise alignment. Thus the processing steps increase. Therefore, the production efficiency of the waveguide devices is reduced.

Thus there is a need to provide a manufacturing device and a manufacturing method for polymer waveguide elements that produce polymer waveguide devices with 45 degree inclined planes without complicated manufacturing processes so as to reduce the cost.

### SUMMARY OF THE INVENTION

Therefore it is a primary object of the present invention to provide a manufacturing device for polymer waveguide devices and a manufacturing method thereof that produce polymer waveguide devices by a femtosecond laser emitting to a photoresist polymer membrane. Thus there is no need to produce 45 degree inclined planes by laser machining. Without complicated manufacturing processes, the production efficiency of polymer waveguide devices is improved.

The manufacturing device for polymer waveguide devices consists of a work platform, a substrate, a femtosecond laser and a lens. The substrate is coated with a photoresist polymer membrane and is set on a work platform. The femtosecond laser emits onto the photoresist polymer membrane and the lens is arranged between the femtosecond laser and the substrate.

The manufacturing method of polymer waveguide devices includes a plurality of steps. Firstly, provide a substrate. Then the substrate is coated with a photoresist polymer membrane. Next the substrate is set on a work platform. Use a femtosecond laser that emits laser beams to the photoresist polymer membrane to form a polymer waveguide element. At last, use a developer to wash the polymer waveguide element. By the femtosecond laser emitting onto the photoresist polymer membrane, polymer waveguide devices are obtained. Thus the production efficiency of the polymer waveguide devices is improved without complicated manufacturing processes.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic drawing showing an embodiment of a manufacturing device for polymer waveguide devices according to the present invention;

FIG. 2 is a flow chart showing manufacturing processes of an embodiment of a manufacturing method for polymer waveguide devices according to the present invention;

FIG. 3 is a flow chart of another embodiment of a manufacturing method for polymer waveguide devices according to the present invention;

FIG. 4A is a schematic drawing showing an embodiment of a polymer waveguide device according to the present invention;

FIG. 4B is a schematic drawing showing another embodiment of a polymer waveguide device according to the present invention;

FIG. 4C is a schematic drawing showing a further embodiment of a polymer waveguide device according to the present invention; and

FIG. 5 is a flow chart of a further embodiment of a manufacturing method for polymer waveguide devices according to the present invention.

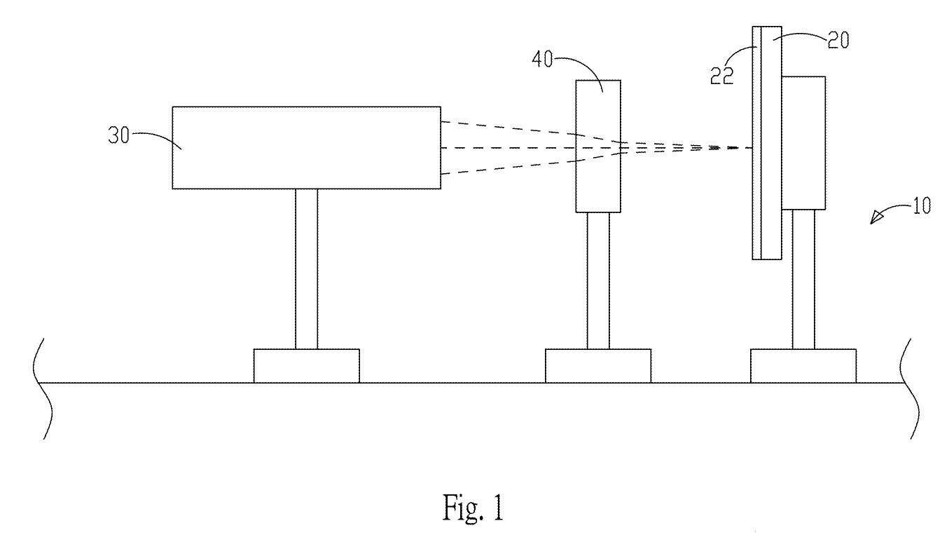

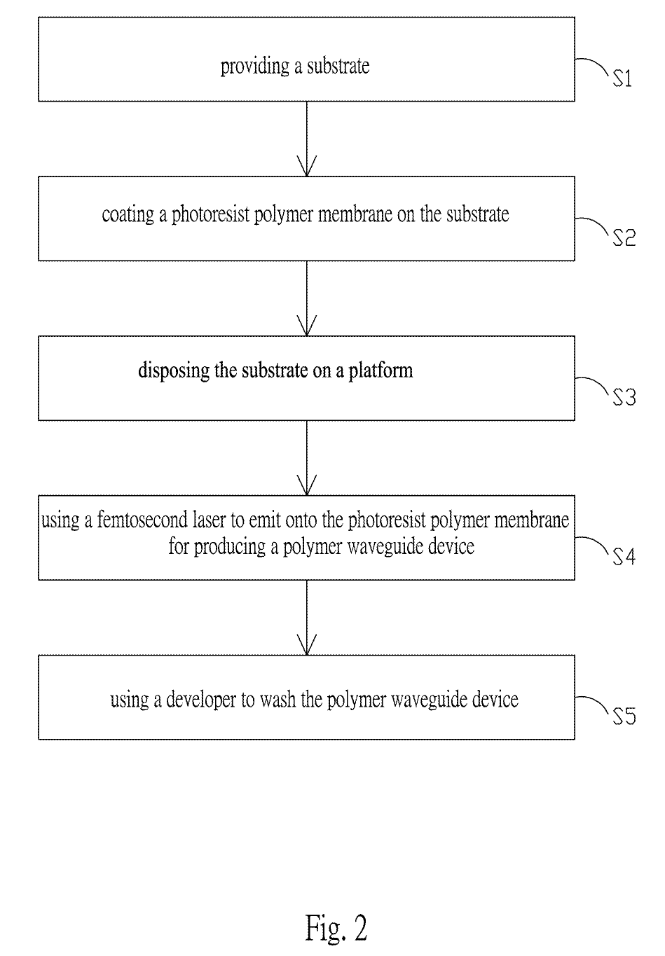

### DETAILED DESCRIPTION OF THE PREFERRED EMBODIMENT

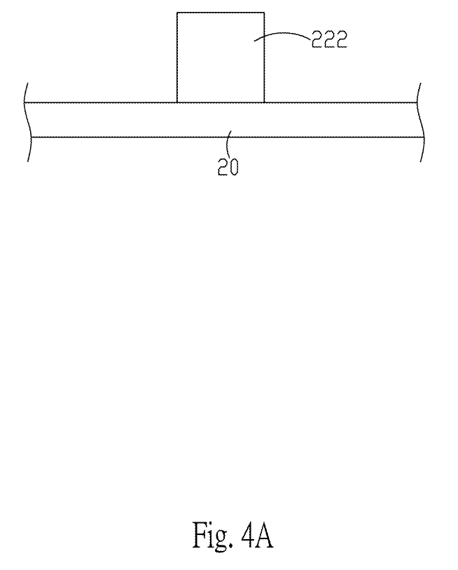

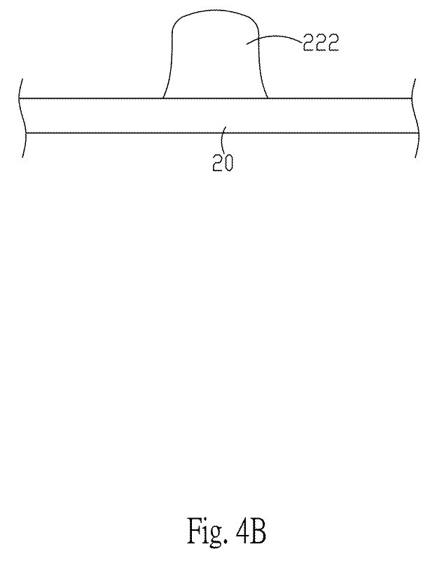

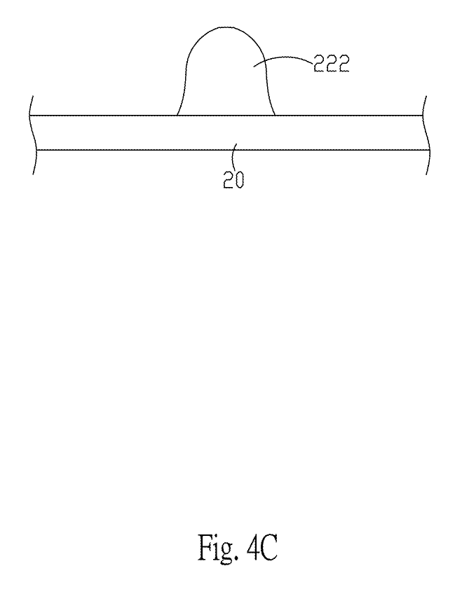

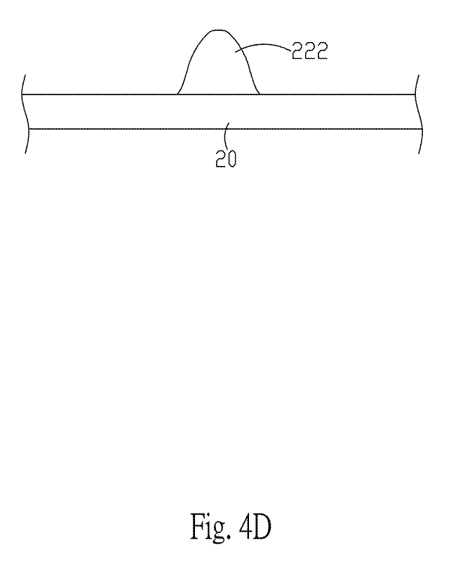

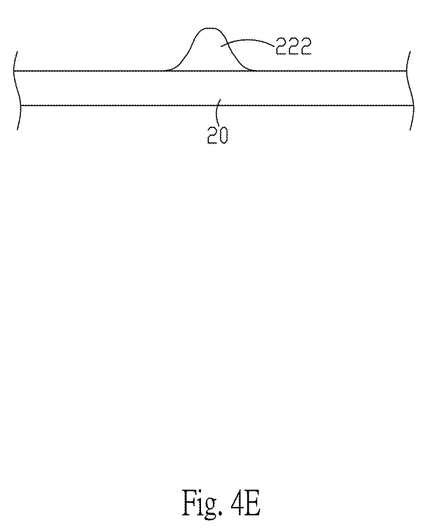

A manufacturing device includes a work platform 10, a substrate 20, a femtosecond laser 30 and a lens 40. The substrate 20 coated with a photoresist polymer membrane 22 is set on the work platform 10. The femtosecond laser 30 emits onto the photoresist polymer membrane 22 to generate a polymer waveguide element 222, as shown from FIG. 4A to FIG. 4E. The lens 40 is disposed between the femtosecond laser 30 and the substrate 20. Next a developer (not shown in figure) is used to wash photoresist polymer membrane 22 so as to get the polymer waveguide element 222.

The femtosecond laser 30 generates pulses in femto second scale (fs, (10⁻¹⁵ second). The femtosecond laser 30 includes a femtosecond Cr:forsterite laser and a femtosecond Ti:sapphire laser. The femtosecond Cr:forsterite laser operates at 1230-nm with a 100-fs. At a 110 MHz repetition rate, the output power could be as high as 300-500 mW. The Ti:Sapphire laser is tuned from 700 nm to 900 nm, with an average output power of up to 1.5 W, minimum pulse widths of 30 fs and highest repetition rate of 2 GHz. Through Transition in the double-frequency, a blue light pulsed laser (350 nm˜450 nm) is generated. In combination with an optical parametric oscillator, a wavelength ranging from 1 mm to 2 mm is produced. The femtosecond laser 30 used in the present embodiment is femtosecond Ti:sapphire laser.

The waveguide devices are fabricated using two photon absorption induced polymerization by Ti:sapphire femtosecond laser. The two photon absorption is far more difficult than the single photon absorption so that the two photon absorption only occurs in focus area. The laser light is focused via the lens 40 onto a layer of photoresist 22. Due to high instantaneous power of the laser pulse, the two photon absorption is induced and polymerization occurs in the photoresist polymer membrane 22. That means the portion of the photoresist polymer membrane 22 emitted by the laser light is exposed and the unexposed portion of the photoresist polymer membrane 22 is washed out by the developer so as to get the waveguide devices.

While manufacturing polymer waveguide devices, firstly take the step S1—provide a substrate 20. The substrate 20 is made from silicon or silicon oxide. Then run the step S2, coat a photoresist polymer membrane 22 on the substrate 20. The material for the photoresist polymer membrane 22 includes epoxy resin (EPO). Next, take the step S3, dispose the substrate 20 on a work platform 10 that is a movable platform or a rotating platform for moving or rotating the substrate 20 after fixing the substrate 20. Later, take the step S4, use a femtosecond laser 30 that emits laser beams to the photoresist polymer membrane 22 to form a polymer waveguide element. The femtosecond laser 30 is with wavelength of 790 nm, pulse width of 120 fs and pulse rate of 80 MHz and an average output power of 1 W. A lens 40 is disposed between the femtosecond laser 30 and the substrate 20 while optimal position of the substrate 20 is the focus position of the lens 40. At last, run the step S5, use a developer to wash the polymer waveguide element for removing unexposed photoresist polymer membrane 22. Thus by the femtosecond laser 30 emitting onto the photoresist polymer membrane 22, polymer waveguide devices are obtained. Therefore, the production efficiency of the polymer waveguide devices is improved without complicated manufacturing processes.

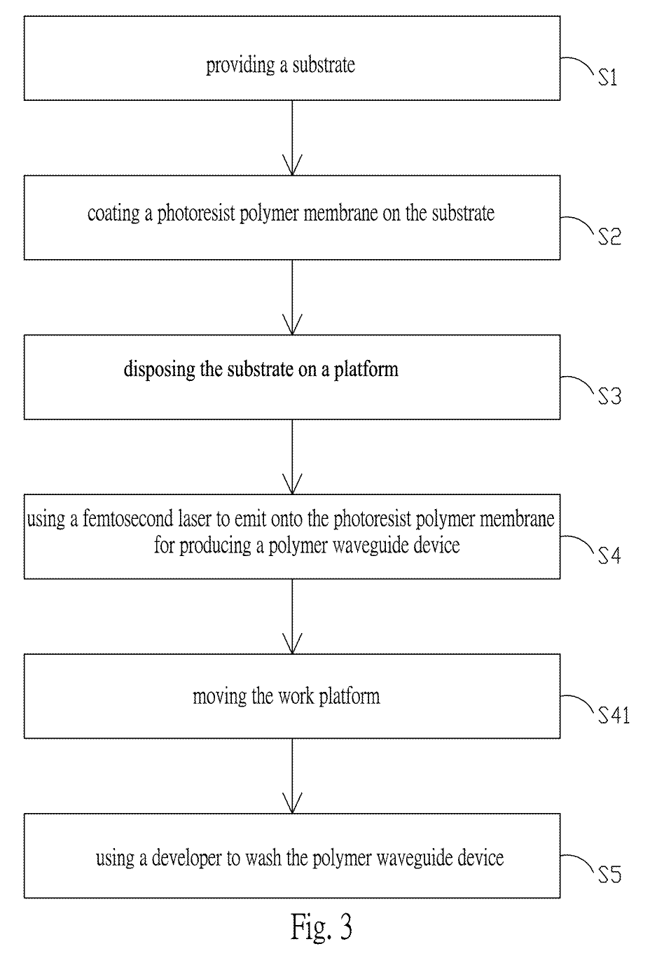

Refer to FIG. 3, FIG. 4A to FIG. 4E, a flow chart of another embodiment according to the present invention and polymer waveguide devices with various focuses are disclosed. As show in the figure, the difference between the embodiment in FIG. 3 and above embodiment is in that the embodiment in FIG. 3 further includes a step S41 after the step S4—move the work platform 10. When the work platform 10 moves linearly, the substrate 20 moves towards the focus of the lens 40 and the polymer waveguide devices 222 produced with various shapes according to the position of the substrate 20. Refer to FIG. 4A, the polymer waveguide device 222 generated at the focus of the lens 40 is rectangular. Keep moving the work platform 150 μm further, the shape of a cross section of the generated polymer waveguide device 222 is similar to a trapezoid, as shown in FIG. 4B. The trapezoid includes two parallel sides and two inclined sides. Once the distance of movement is controlled properly, the inclined surface of the device is inclined at an angle of 45 degrees. The platform 10 is moved further, up to 150 μm. The polymer waveguide device 222 produced is as shown in FIG. 4C, the rectangular polymer waveguide device 222 becomes a cylinder. The platform 10 is moved another 150 μm and the polymer waveguide device 222 looks like a sand dune, as shown in FIG. 4D. Keep moving the work platform 10 for another 150 μm and the polymer waveguide device 222 becomes a tiny bump, as shown in FIG. 4E. Thus it is learned that the shape of the polymer waveguide device 222 varies along with different distance between the substrate 20 and the focus. Therefore, the polymer waveguide devices 222 with various shapes are obtained by adjusting the distance between the substrate 20 and the focus.

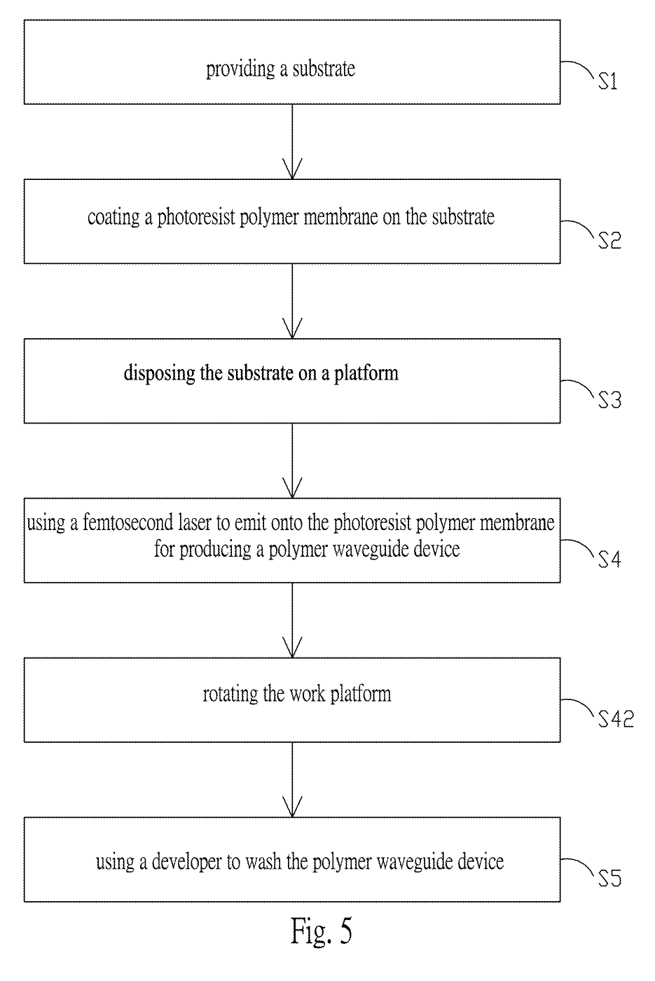

Refer to FIG. 5, a further embodiment of the present invention is disclosed. The difference between this embodiment and the above one is in that after the step S4, a step S42 is further included. The step S42 is to rotate the platform 10. Instead of being moved, the platform 10 is rotated according to the shape of the polymer waveguide devices 222. Thus the angle of the inclined surface of the polymer waveguide devices 222 is adjusted by the rotation of the platform 10.

In summary, a manufacturing device for optical waveguide devices consists of a work platform, a substrate coated with a photoresist polymer membrane set on the work platform, a femtosecond laser emitting onto the photoresist polymer membrane, and a lens arranged between the femtosecond laser and the substrate. The polymer waveguide devices are obtained by the femtosecond laser emitting onto the photoresist polymer membrane. Without complicated manufacturing processes, the production efficiency of the polymer waveguide devices is improved.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A manufacturing device for polymer waveguide devices comprising:
a work platform,
a substrate coated with a photoresist polymer membrane set on the work platform,
a femtosecond laser emitting onto the photoresist polymer membrane to generate a polymer waveguide device, and
a lens arranged between the femtosecond laser and the substrate.

2. The device as claimed in claim 1, wherein the device further having a developer for washing the photoresist polymer membrane.

3. The device as claimed in claim 1, wherein the work platform is a movable platform.

4. The device as claimed in claim 1, wherein the work platform is a rotating platform.

5. The device as claimed in claim 1, wherein the femtosecond laser is a femtosecond Ti:sapphire laser.

6. The device as claimed in claim 1, wherein the substrate is made from silicon.

7. The device as claimed in claim 1, wherein the substrate is made from silicon oxide.

8. The device as claimed in claim 1, wherein the photoresist polymer membrane is made from epoxy resin (EPO).

9. The device as claimed in claim 1, wherein wavelength of the femtosecond laser is 790 nm.

10. The device as claimed in claim 1, wherein pulse width of the femtosecond laser is 120 fs.

11. The device as claimed in claim 1, wherein pulse rate of the femtosecond laser is 80 MHz.

12. The device as claimed in claim 1, wherein average output power of the femtosecond laser is 1 W.

13. A manufacturing method for polymer waveguide devices comprising the steps of:
providing a substrate;
coating a photoresist polymer membrane on the substrate;
using a femtosecond laser to emit onto the photoresist polymer membrane for producing a polymer waveguide device; and
using a developer to wash the polymer waveguide device.

14. The method as claimed in claim 13, wherein after the step of coating a photoresist polymer membrane on the substrate, the method further comprising a step of: disposing the substrate on a platform.

15. The method as claimed in claim 13, wherein after the step of using a femtosecond laser to emit onto the photoresist polymer membrane for producing a polymer waveguide device, the method further comprising a step of moving the work platform.

16. The method as claimed in claim 15, wherein the work platform is a movable platform.

17. The method as claimed in claim 13, wherein the step of after the step of using a femtosecond laser to emit onto the photoresist polymer membrane for producing a polymer waveguide device, the method further comprising a step of rotating the work platform.

18. The method as claimed in claim 17, wherein the work platform is a rotating platform.

19. The method as claimed in claim 13, wherein the femtosecond laser is a femtosecond Ti:sapphire laser.

20. The method as claimed in claim 13, wherein the substrate is made from silicon.

21. The method as claimed in claim 13, wherein the substrate is made from silicon oxide.

22. The method as claimed in claim 13, wherein the photoresist polymer membrane is made from epoxy resin (EPO).

23. The method as claimed in claim 13, wherein wavelength of the femtosecond laser is 790 nm.

24. The method as claimed in claim 13, wherein pulse width of the femtosecond laser is 120 fs.

25. The method as claimed in claim 13, wherein pulse rate of the femtosecond laser is 80 MHz.

26. The method as claimed in claim 13, wherein average output power of the femtosecond laser is 1 W.
